(19) United States
(12) Patent Application Publication
(10) Pub. No.: US 2013/0301214 A1
(43) Pub. Date: Nov. 14, 2013

(54) ELECTRONIC UNIT HAVING A HOUSING IN WHICH HEAT GENERATING COMPONENTS ARE DISPOSED

(71) Applicants: Christian Böhm, Mertingen (DE); Philipp Rauw, Augsburg (DE)

(72) Inventors: Christian Böhm, Mertingen (DE); Philipp Rauw, Augsburg (DE)

(73) Assignee: Fujitsu Technology Solutions Intellectual Property GmbH, Munchen (DE)

(21) Appl. No.: 13/992,066

(22) PCT Filed: Dec. 5, 2011
(86) PCT No.: PCT/EP2011/071715

§ 371 Date: Jul. 23, 2013

(30) Foreign Application Priority Data
Dec. 13, 2010 (DE) 102010054281.4

(51) Int. Cl. G06F 1/20; H05K 7/20

(52) U.S. Cl. CPC G06F 1/20; H05K 7/2039
USPC 361/679.54; 361/707; 361/695; 361/700; 361/709

(57) ABSTRACT

An electronic unit having a housing including a heat generating first component, a heat generating second component and a cooling system disposed in the housing, wherein during operation of the unit, the first and second components are cooled by the cooling system, and the first component connects to the second component via a heat-conducting connection such that a lower temperature of the first component and a higher temperature of the second component converge.

### TECHNICAL FIELD

This disclosure relates to an electronic unit having a housing, wherein a heat generating first component, a heat generating second component and a cooling system are disposed in the housing. During operation of the unit, the first and second components are cooled by the cooling system.

### BACKGROUND

Electronic units, in particular computer systems, normally comprise a plurality of heat generating components or devices, for example, processors (Central Processing Units=CPUs), random access memory devices (Random Access Memory=RAM), system boards or other such components. Each component dissipates power, this power dissipation manifesting itself at the component in the form of emitted heat. This emitted heat can be conducted away from the components and dissipated outside to the surroundings by a cooling system, normally a fan system that generates a cooling air flow or a water cooling system. Usually a heatsink that has cooling fins or cooling vanes and significantly improves the heat emission is arranged against or on the components.

The heat generating components in such systems normally have different operating temperatures depending on the load on the respective components and the interface of the components to the cooling system. Specifically in multiple-socket systems (systems containing two or more processors), the processors may have different loads and/or may be positioned such that only an imbalanced cooling effect can be achieved. In this case, the cooling system must be designed such that all the components, including those that have a high operating temperature, are cooled effectively so that the system does not suffer damage and failure.

This means that the cooling system must always be designed on the basis of the maximum operating temperature of one component the system. Thus cooling of other components that have lower operating temperatures is disproportionately powerful, wherein the cooling effort expended on these components is excessively high, causing unnecessary costs.

Known solutions are mostly aimed at optimizing the guidance of a cooling medium. Thus, for instance, complex air-guidance measures via air duets are used generally in combination with a deployment of additional fans. Alternatively, water cooling systems are used which displace the position in which heat is transferred to the surrounding air. A further alternative is to use heatsinks having various properties as regards heat transfer and emission to the surrounding air.

These solutions have the disadvantage, however, that they involve increased development costs for a limited service life of the components used, combined with high maintenance costs (for example, for the water cooling system), and only provide a very limited countermeasure to an imbalanced cooling effect. This results in high system costs.

It could therefore be helpful to provide an electronic unit, wherein the cooling of all the heat generating components in the unit can be improved.

### SUMMARY

We provide an electronic unit having a housing including a heat generating first component, a heat generating second component and a cooling system disposed in the housing, wherein during operation of the unit, the first and second components are cooled by the cooling system, and the first component connects to the second component via a heat-conducting connection such that a lower temperature of the first component and a higher temperature of the second component converge.

### BRIEF DESCRIPTION OF THE DRAWINGS

FIG. 1 shows a first example of an electronic unit.

FIG. 2 shows a second example of a unit.

FIG. 3 shows a perspective view of a further example of an electronic unit.

### LIST OF REFERENCES

1 electronic unit
2 housing
3 heat generating first component
4 heat generating second component
5 cooling system
6 heat-conducting connection
7 cooling air flow
8 outgoing air flow
9 further components
10 heat transfer

### DETAILED DESCRIPTION

We provide an electronic unit, wherein the first heat generating component is connects to the second heat generating component via a heat-conducting connection such that a lower temperature of the first component and a higher temperature of the second component converge.

This has the advantage that emitted heat can be exchanged between the two components so that emitted heat from the hotter component is transported to the cooler component via the heat-conducting connection. Although the consequence of this is that the cooler component is heated slightly, it has the advantage that the hotter component is cooled slightly. Thus, the temperature of the hotter component can be lowered and, therefore, the cooling power of the cooling system can also be reduced.

The heat adjustment or heat balancing between the two components means that a more moderate figure can be specified for the difference between the operating temperatures of the two components and, therefore, the cooling power of the cooling system can also be designed to be more moderate. For fan systems, this means, for example, reducing the speed, with an associated reduction in the noise emission. For a water cooling system, this means, for example, reducing the pumping rate for the cooling agent.

The components are cooled more efficiently, wherein the surplus of cooling power with reference to the first, cooler component can be kept lower than in conventional solutions.

The temperature of the first component and the temperature of the second component are preferably evened out to an approximately equal temperature level. Thus, the operating temperatures of both components in this case are approximately equal and lie between the operating temperature of the first component and the operating temperature of the second component that would arise without heat transfer between the two components. In this case, the cooling power can be controlled, because the first component is not cooled too much and the second component is not cooled too little. A surplus of cooling power with reference to the first component is thereby minimized.

Regarding the entire system as well, this has the advantage that regional or local heat sources or heat sinks and, hence, a temperature imbalance in the system housing, can be evened out to the greatest possible extent. Temperature differences in the operating temperatures of the components are evened out by the heat-conducting connection.

Of course, the heat exchange between a hotter component and a cooler component is designed such that the cooler component does not suffer damage from being heated. Therefore, this solution is used in particular for components of similar architecture and/or functionality, for example, between two processors.

The first component may be arranged in the direction of a cooling air flow of the cooling system, in front of the second component such that at least some of the outgoing air flow from the first component impinges on the second component. This example and the spatial arrangement of the two components are used, for example, in multiple socket systems (specifically in two-socket systems), wherein the components are arranged in one housing in a space-saving manner occupying a small component volume.

This has the disadvantage, however, that the second component which lies in the outgoing air flow behind the first component, is heated additionally as a result of the air heated by the emitted heat from the first component. Furthermore, the second component lies in the shadow of the first component and, therefore, also only some of the cooling air from the cooling system reaches the second component. All these factors result in a temperature imbalance between the two components, which can be reduced because of the heat-conducting connection between the two components.

The heat-conducting connection preferably comprises a heat pipe. This is used in particular for thermal conduction between a heat source (in this case the hotter component) and a heat sink in this case the cooler component). Thermal conduction in the heat pipe enables convergence of the operating temperatures of the two components.

Our electronic units are described in greater detail with reference to as plurality of examples shown in the drawings.

FIG. 1 shows a first example of an electronic unit 1 having a housing 2. In the housing 2 are disposed by way of example two heat generating components, namely a first component 3 and a second component 4. Both components 3 and 4 may be, for example, two processors in a computer system or the like. A cooling system 5, here in the form of a fan by way of example, is also disposed in the housing 2 for the purpose of cooling the two components 3 and 4. The cooling system 5 generates a cooling air flow 7, which initially impinges on the first component 3 and then on the second component 4. A ventilation hole (not shown), for example, located behind the second component 4 in the direction of the cooling air flow 7, can be provided on an outer wall of the housing 2 to dissipate the emitted heat generated to outside the housing 2.

This arrangement of the components 3 and 4, in which the components lie one behind the other in the direction of the cooling air flow 7, results in the disadvantage that an outgoing air flow 8 heated by the first component 3 impinges on the second component 4. In addition, the second component 4 lies partly in the shadow of the first component 3 as regards the cooling air flow 7 and, therefore, only some of the cooling air flow 7. Hence, only some of a fresh air flow impinges on the second component 4.

For these reasons and also for reasons of different power and performance of the two components 3 and 4, the second component 4 may become warmer than the first component 3. An imbalance between the operating temperatures of the first component 3 and the second component 4 therefore exists in the housing 2.

The components 3 and 4 connect together via a heat-conducting connection 6, wherein as a result of physical laws of thermodynamics, the emitted heat from both heat sources, i.e. the components 3 and 4, is evened out between the components. This means that a higher level of emitted heat from the component 4 is transported to the cooler component 3, thereby heating the cooler component 3 slightly yet cooling the hotter component 4 slightly. This heat transfer is symbolized by the solid arrow 10.

Thus, the heat-conducting connection 6 between the two components 3 and 4 results in convergence of the two operating temperatures of the components 3 and 4, wherein in the ideal case, the operating temperatures are evened out to an approximately equal temperature level that lies between the two operating temperatures.

The heat-conducting connection 6 comprises, for example, a heat pipe. The heat pipe or heat conducting pipe can comprise, for example, an outer casing and an internal capillary mesh in which a working fluid, for example, water, is transported. The capillary mesh can be formed, for example, by a copper wire mesh having a high thermal conductivity line advantage or such a heat pipe is that the heat can be transported particularly effectively because a flow of the working fluid is maintained through the wick structure of the capillary mesh in the heat pipe. The result is that a large amount of heat can be transferred in the heat pipe. Such heat capes are widely used in computer system applications.

The heat-conducting connection can also be formed, for example, by a metal or copper bridge between the two components 3 and 4, wherein a heat flow is established from the warmer component 4 to the cooler component 3 as a result of a temperature gradient between the components 3 and 4.

It is also possible to provide a heatsink on the heat-conducting connection 6, wherein heat can be dissipated at the heatsink in addition to the heat transport in the heat-conducting connection 6, thereby enabling an overall improvement in the heat dissipation from the hotter component 4.

The cooling power of the cooling system 5 can be reduced by the measures described because the maximum operating temperature to be cooled, in this case the operating temperature of the hotter component 4, is reduced. In addition, a balanced temperature relationship is produced in the housing 2, wherein regional zones of various heat sources and heat sinks can be evened out, at least in part.

A reduction in the cooling power of the cooling system means, for example, according to the example in FIG. 1, a reduction in the fan speed and hence a reduction in the noise emission in the electronic unit 1.

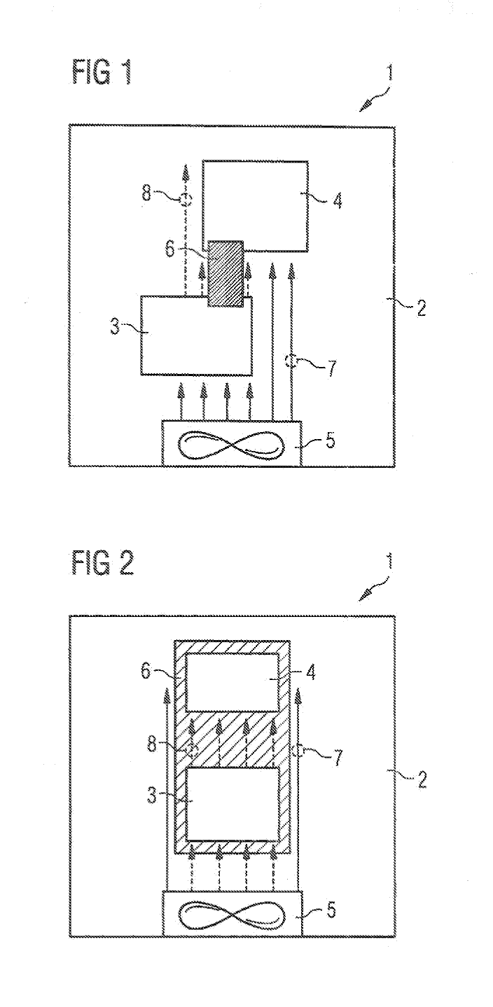

FIG. 2 shows a second example of an electronic unit 1 having a housing 2, wherein again the housing 2 contains two components 3 and 4, which have different operating temperatures according to the load on the components. In this example, a cooling system 5 in the form of a fan again cools the two components 3 and 4 by generating a cooling air flow 7. According to the example in FIG. 2, the components 3 and 4 and are not offset from one another as in FIG. 1, but lie directly behind one another in the direction of the cooling air flow 7. Such an arrangement is necessary, for example, in compact electronic units 1 having a high component density for a small component volume.

This means that almost the entire heated outgoing air flow 8 from the first component 3, and almost no fresh air from the cooling air flow 7, reaches the second component 4. Thus, in this case, a high imbalance between the operating temperatures of the components 3 and 4 can be expected. To even out the operating temperatures and conduct away heat from the hotter component 4 to the cooler component 3 (see solid arrow 10), the two components 3 and 4 are arranged on a heat-conducting connection 6, which is in the form of a plate in this case. The heat-conducting connection 6 can work here according to any of the principles explained above.

The operating temperatures of the components 3 and 4 can converge and are preferably evened out to a practically uniform temperature level. This reduces the maximum operating temperature, namely the temperature of the hotter component 4 and, therefore, the power of the cooling system 5 can likewise be reduced. As already explained, this has the advantage that the cooler component 3 is not cooled disproportionately and the hotter component 4 is still cooled sufficiently.

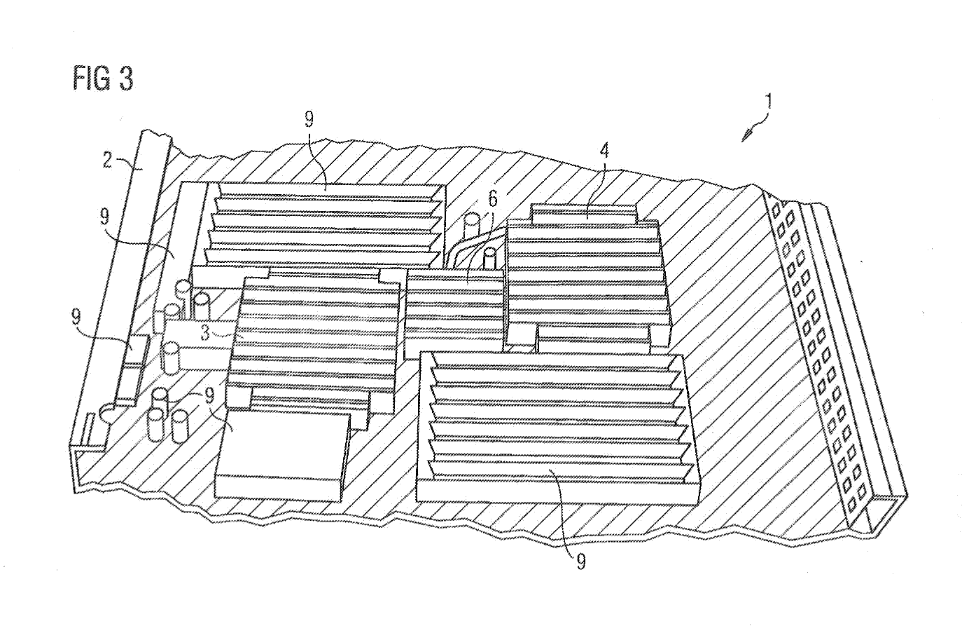

FIG. 3 shows a perspective view of an example of an electronic unit 1, wherein part of housing 2 is shown schematically. In the housing 2 is disposed a heat generating first component 3 and a heat generating second component 4 and also a heat-conducting connection 6 between the two components 3 and 4. The components 3 and 4 and the heat-conducting connection 6 have heatsinks, the cooling fins or cooling vanes of which lie in a cooling air flow from a cooling system (not shown). Emitted heat can thereby be dissipated from the components 3 and 4 and from the heat-conducting connection 6 as a result of convection. The heat-conducting connection 6 between the two components 3 and 4 results in the operating temperatures of the components 3 and 4 almost achieving equilibrium at a level that lies between a maximum operating temperature of the hotter component 4 and the lower operating temperature of the cooler component 3. A heat flow established as a result of the heat-conducting connection 6 from the hotter component 4 to the cooler component 3 is in the opposite direction to the cooling air flow from the cooling system.

In addition, the housing 2 contains further components 9, for example, slots for random access memory devices (RAM), expansion boards or daughter boards, and electronic components. The components 3 and 4 are, for example, processors of a computer system.

The two components 3 and 4 are in an offset arrangement in this example, similar to the example of FIG. 1. It is also possible, however, to arrange the components 3 and 4 according to an arrangement of FIG. 2. This depends on how the system board is populated in the electronic unit 1.

in examples that are not shown, it is also possible, for example, for a plurality of components to connect via a plurality of heat-conducting connections such that all the operating temperatures of all the connected components converge and advantageously even out to an almost equal temperature level. All the operating temperatures of all the connected components, are hence averaged out, allowing the maximum operating temperature of the hottest component to be lowered. This has the advantage that a cooling system in such a unit merely needs to be designed for the average operating temperature. Owing to the heat-conducting, connections between all the components, an even heat level is established in the unit, wherein spatially distributed heat sources or heat sinks can be evened out.

The heat-conducting connection can be in many different forms. It is possible to provide merely a metal or copper bridge or a suitable plate-shaped connection for heat conduction, or more complex designs such as a heat pipe or a thermosiphon, for instance. Various working fluids, for example, water or cooling agent can flow through such designs. The thermal conductivity of the heat-conducting connection 6 must be adapted to suit the relevant application.

In addition, the cooling system 5 may comprise any form of cooling system, for example a fan system or a fluid cooling system using a fluid such as water or coolant, or a combination of these designs. The alternatives shown are given merely by way of example.

1.-9. (canceled)

10. An electronic unit having a housing comprising:
a heat generating first component,
it heat generating second component, and
a cooling system disposed in the housing,
wherein during operation of the unit, the first and second components are cooled by the cooling system, and the first component connects to the second component via a heat-conducting connection such that a lower temperature of the first component and a higher temperature of the second component converge.

11. The electronic unit according to claim 10, wherein a temperature of the first component and a temperature of the second component are evened out to an approximately equal temperature level.

12. The electronic unit according to claim 10, wherein the cooling system comprises at least one fan which generates a cooling air flow.

13. The electronic unit according to claim 12, wherein the first component is arranged, in a direction of the cooling air flow, in front of the second component such that at least some of the outgoing air flow from the first component impinges on the second component.

14. The electronic unit according to claim 10, wherein the heat-conducting connection comprises a heat pipe.

15. The electronic unit according to claim 10, wherein at least one of the first and second components has a heatsink that dissipates generated heat.

16. The electronic unit according to claim 10, wherein the heat-conducting connection has a heatsink.

17. The electronic unit according to claim 10, wherein the unit is a computer system.

18. The electronic unit according to claim 17, wherein the first and second components each comprise a processor.

19. The electronic unit according to claim 11, wherein the cooling system comprises at least one fan which generates a cooling air flow.

20. The electronic unit according to claim 19, wherein the first component is arranged, in a direction of the cooling air flow, in front of the second component such that at least some of the outgoing air flow from the first component impinges on the second component.

21. The electronic unit according to claim 11, wherein the heat-conducting connection comprises a heat pipe.

22. The electronic unit according to claim 12, wherein the heat-conducting connection comprises a heat pipe.

23. The electronic unit according to claim 13, wherein the heat-conducting connection comprises a heat pipe.

24. The electronic unit according to claim 11, wherein at least one of the first and second components has a heatsink that dissipates generated heat.

25. The electronic unit according to claim 12, wherein at least one of the first and second components has a heatsink that dissipates generated heat.

26. The electronic unit according to claim 13, wherein at least one of the first and second components has a heatsink that dissipates generated heat.

27. The electronic unit according to claim 14, wherein at least one of the first and second components has a heatsink that dissipates generated heat.
